(19) United States
(12) Patent Application Publication
(10) Pub. No.: US 2024/0136792 A1
(43) Pub. Date: Apr. 25, 2024

(54) SURFACE EMITTING LASER APPARATUS AND METHOD FOR MANUFACTURING THE SAME

(71) Applicant: HLJ TECHNOLOGY CO., LTD., HSINCHU COUNTY (TW)

(72) Inventors: LI-HUNG LAI, HSINCHU COUNTY (TW); LI-WEN LAI, HSINCHU COUNTY (TW)

(21) Appl. No.: 18/155,035

(22) Filed: Jan. 16, 2023

(30) Foreign Application Priority Data
Oct. 18, 2022 (TW) 111139580

(51) Int. Cl. H01S 5/183

(52) U.S. Cl. CPC H01S 5/18308; H01S 5/18327

(57) ABSTRACT

A surface emitting laser apparatus and a method for manufacturing the same are provided. The surface emitting laser apparatus includes a first reflector layer, an active light-emitting layer, a second reflector layer, and a current confinement layer. The active light-emitting layer is disposed between the first reflector layer and the second reflector layer, so as to produce a laser beam. The current confinement layer is disposed above or below the active light-emitting layer. The current confinement layer is a semiconductor layer, and an energy gap width of the current confinement layer is greater than an energy gap width of the active light-emitting layer.

### CROSS-REFERENCE TO RELATED PATENT APPLICATION

This application claims the benefit of priority to Taiwan Patent Application No. 111139580, filed on Oct. 19, 2022. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a surface emitting laser apparatus and a method for manufacturing the same, and more particularly to a vertical cavity surface emitting laser apparatus and a method for manufacturing the same.

### BACKGROUND OF THE DISCLOSURE

A conventional vertical cavity surface emitting laser at least includes a P-type electrode, an N-type electrode, an active layer for production of photons, and an upper distributed Bragg reflector (DBR) as well as a lower DBR that are respectively disposed on two sides of the active layer. Through applying a bias voltage to the P-type electrode and the N-type electrode, a current is injected into the active layer to excite the photons. Further, the upper DBR and the lower DBR are used to form a vertical resonant cavity, such that a laser beam emitted from a surface of a component (i.e., in a direction perpendicular to the active layer) can be produced.

In the conventional vertical cavity surface emitting laser, an oxide layer or an ion implantation region with high resistance is usually formed on the upper DBR by an ion implantation process or a wet oxidation process, so as to confine a region through which the current flows. However, when the oxide layer or the ion implantation region for confining the current is formed by the ion implantation process or a thermal oxidation process, the costs are high and a hole size cannot be easily controlled.

In addition, there are great differences between the oxide layer and a semiconductor material of the upper DBR in terms of a lattice mismatch and a thermal coefficient of expansion, thereby causing the vertical cavity surface emitting laser to be easily broken due to an internal stress after an annealing process and a manufacturing yield to be reduced. The internal stress of the component also reduces the lifespan of the component, affects lighting characteristics, and decreases the reliability.

### SUMMARY OF THE DISCLOSURE

In response to the above-referenced technical inadequacies, the present disclosure provides a surface emitting laser apparatus and a method for manufacturing the same, so as to decrease an internal stress of the surface emitting laser apparatus and improve reliability of the surface emitting laser apparatus.

In one aspect, the present disclosure provides a surface emitting laser apparatus, which includes a first reflector layer, an active light-emitting layer, a second reflector layer, and a current confinement layer. The active light-emitting layer is disposed between the first reflector layer and the second reflector layer so as to produce a laser beam. The current confinement layer is disposed above or below the active light-emitting layer. The current confinement layer is a semiconductor layer, and an energy gap width of the current confinement layer is greater than an energy gap width of the active light-emitting layer.

In another aspect, the present disclosure provides a surface emitting laser apparatus, which includes a first reflector layer, an active light-emitting layer, a second reflector layer, and a current confinement layer. The active light-emitting layer is disposed between the first reflector layer and the second reflector layer so as to produce a laser beam. The current confinement layer is disposed in the first reflector layer or the second reflector layer, and includes at least one doping semiconductor layer. When the current confinement layer is disposed in the first reflector layer, the doped semiconductor layer and the first reflector layer have different conductivity types. When the current confinement layer is disposed in the second reflector layer, the doped semiconductor layer and the second reflector layer have different conductivity types.

In yet another aspect, the present disclosure provides a method for manufacturing a surface emitting laser apparatus, which includes: forming a first reflector layer; forming an active light-emitting layer on the first reflector layer; forming a current confinement layer; and forming a second reflector layer. The current confinement layer defines a confinement hole, and a material of the current confinement layer is an intrinsic semiconductor or a doped semiconductor.

One of the beneficial effects of the present disclosure is that, in the surface emitting laser apparatus and the method for manufacturing the same provided by the present disclosure, by virtue of “the current confinement layer being the semiconductor layer, and the energy gap width of the current confinement layer being greater than the energy gap width of the active light-emitting layer,” the internal stress of the surface emitting laser apparatus can be reduced, thereby allowing the surface emitting laser apparatus to have improved reliability.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic cross-sectional view of a surface emitting laser apparatus according to a first embodiment of the present disclosure;

FIG. 2 is a schematic cross-sectional view of a surface emitting laser apparatus according to a second embodiment of the present disclosure;

FIG. 3 is a schematic cross-sectional view of a surface emitting laser apparatus according to a third embodiment of the present disclosure;

FIG. 4 is a schematic cross-sectional view of a surface emitting laser apparatus according to a fourth embodiment of the present disclosure;

FIG. 5 is a schematic cross-sectional view of a surface emitting laser apparatus according to a fifth embodiment of the present disclosure;

FIG. 6 is a flowchart of a method for manufacturing a surface emitting laser apparatus according to one embodiment of the present disclosure;

FIG. 7 is a schematic view of the surface emitting laser apparatus in step S10 of the method according to the embodiment of the present disclosure;

FIG. 8 is a schematic view of the surface emitting laser apparatus in step S20 of the method according to the embodiment of the present disclosure;

FIG. 9 and FIG. 10 are schematic views of the surface emitting laser apparatus in step S30 of the method according to the embodiment of the present disclosure;

FIG. 11 is a schematic view of the surface emitting laser apparatus in step S40 of the method according to the embodiment of the present disclosure;

FIG. 12 is a schematic view of the surface emitting laser apparatus in step S50 of the method according to the embodiment of the present disclosure;

FIG. 13 is a schematic view of the surface emitting laser apparatus in step S40 of the method according to another embodiment of the present disclosure; and

FIG. 14 is a schematic view of the surface emitting laser apparatus in step S50 of the method according to another embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

### First Embodiment

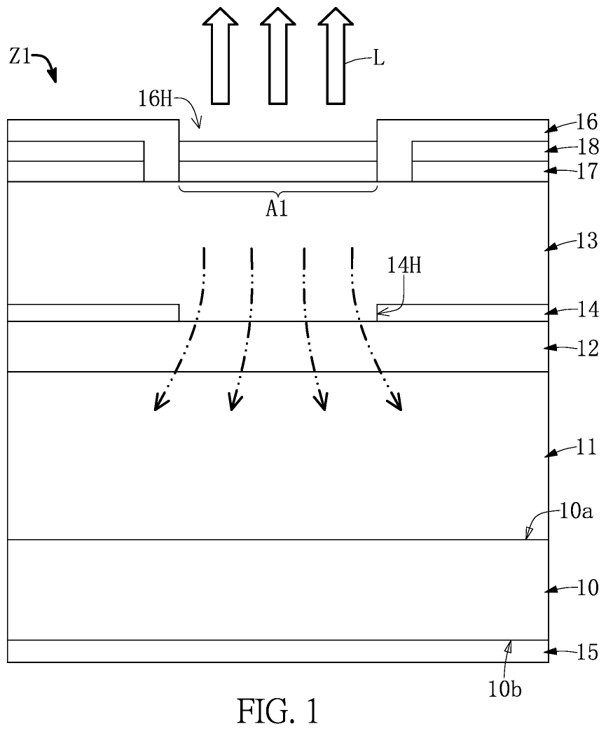

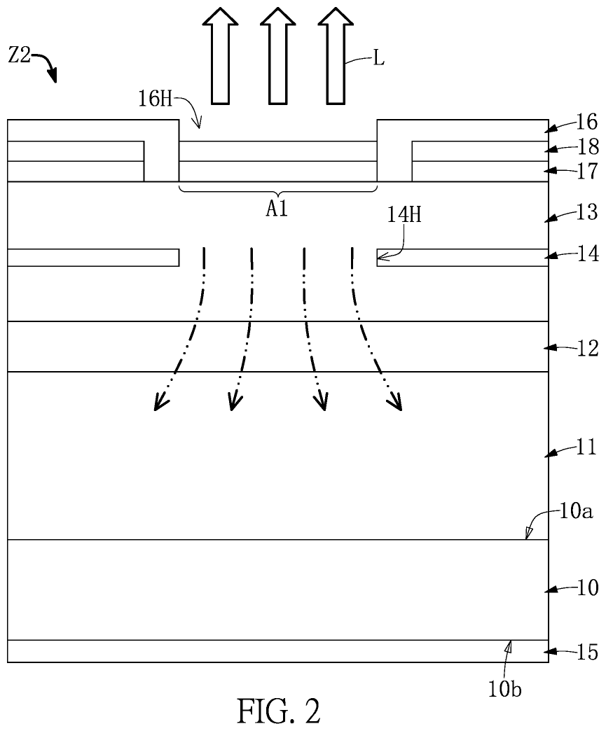

Referring to FIG. 1 and FIG. 2, a first embodiment of the present disclosure provides a surface emitting laser apparatus Z1. In the embodiments of the present disclosure, the surface emitting laser apparatus Z1 is a vertical cavity surface emitting laser apparatus. The surface emitting laser apparatus Z1 includes a first reflector layer 11, an active light-emitting layer 12, a second reflector layer 13, and a current confinement layer 14. Specifically, in the present embodiment, the surface emitting laser apparatus Z1 further includes a substrate 10. The first reflector layer 11, the active light-emitting layer 12, the second reflector layer 13, and the current confinement layer 14 are disposed on the substrate 10, and the active light-emitting layer 12 is arranged between the first reflector layer 11 and the second reflector layer 13.

The substrate 10 can be an insulation substrate or a semiconductor substrate. The insulation substrate can be, for example, a sapphire, and the semiconductor substrate can be, for example, silicon, germanium, silicon carbide, or a group III-V semiconductor. The group III-V semiconductor can be, for example, gallium arsenide (GaAs), arsenic phosphide (AsP), aluminum nitride (AlN), indium nitride (InN), or gallium nitride (GaN). In addition, the substrate 10 has an epitaxial surface 10a and a bottom surface 10b that is opposite to the epitaxial surface 10a.

The first reflector layer 11, the active light-emitting layer 12, and the second reflector layer 13 are sequentially disposed on the epitaxial surface 10a of the substrate 10. In the present embodiment, each of the first reflector layer 11, the active light-emitting layer 12, and the second reflector layer 13 has a cross-sectional width the same as that of the active light-emitting layer 12.

Each of the first reflector layer 11 and the second reflector layer 13 can be a distributed Bragg reflector (DBR) that is formed by alternately stacking two films having different refractive indices, so as to allow light to be resonantly reflected at a predetermined wavelength. In the present embodiment, materials of the first reflector layer 11 and the second reflector layer 13 can be doped group III-V semiconductors, and the first reflector layer 11 and the second reflector layer 13 have different conductivity types.

The active light-emitting layer 12 is formed on the first reflector layer 11 to produce a laser beam L. Specifically, the active light-emitting layer 12 is arranged between the first reflector layer 11 and the second reflector layer 13, and can be excited by electric power to produce an initial beam. The initial beam produced by the active light-emitting layer 12 is resonantly reflected between the first reflector layer 11 and the second reflector layer 13 to be amplified. Eventually, the initial beam is emitted by the second reflector layer 13 to produce the laser beam L.

The active light-emitting layer 12 includes a plurality of layers for formation of a multiple quantum well, such as a plurality of trap layers and a plurality of barrier layers that are alternately stacked on each other and un-doped (not shown). Materials of the trap layer and the barrier layer are determined according to a wavelength of the laser beam L to be produced. For example, when the laser beam L to be produced is red light, the material of the trap layer can be indium gallium phosphide (InGaP). When the laser beam L to be produced is near infrared light, the material of the trap layer can be indium gallium arsenide phosphate (InGaAsP) or indium gallium aluminum arsenide (InGaAlAs). When the laser beam L to be produced is blue light or green light, the material of the trap layer can be indium gallium nitride (InₓGa₍₁₋ₓ₎N). However, the present disclosure is not limited thereto.

Referring to FIG. 1, the current confinement layer 14 included in the surface emitting laser apparatus Z1 is arranged above or below the active light-emitting layer 12. The current confinement layer 14 has a confinement hole 14H, so as to define a current flow pathway. It should be noted that, as long as the current confinement layer 14 can be used to define a region through which a current flows, a position of the current confinement layer 14 is not limited in the present disclosure. In the present embodiment, the current confinement layer 14 is arranged in the second reflector layer 13 and connected to the active light-emitting layer 12. Specifically, in the present embodiment (as shown in FIG. 2), one part of the second reflector layer 13 is filled into the confinement hole 14H and connected to the active light-emitting layer 12. Since the second reflector layer 13 is a doped semiconductor material and has a high electrical conductivity, the current is allowed to flow through the one part of the second reflector layer 13 that is filled into the confinement hole 14H.

In one embodiment, the current confinement layer 14 is an intrinsic semiconductor layer, and has a high resistance to block the current from flowing through. In addition, a material of the current confinement layer 14 can be a semiconductor material that does not absorb the laser beam L. In other words, the material of the current confinement layer 14 can allow the laser beam L to pass through.

It should be noted that, given that the wavelength of the laser beam L is λ (unit: nm), and an energy gap width of the semiconductor material of the current confinement layer 14 is Eg, the energy gap width Eg and the wavelength λ of the laser beam L can satisfy the following relationship: Eg>(1240/λ). In the embodiments of the present disclosure, the laser beam L produced by the surface laser emitting apparatus Z1 is near infrared light, blue light, or green light. For example, when the laser beam L is the near infrared light and the wavelength λ of the laser beam L is 1,550 nm, the energy gap width of the current confinement layer 14 should be greater than 0.8 eV. When the wavelength λ of the laser beam L is 950 nm, the energy gap width of the current confinement layer 14 should be equal to 1.3 eV. Further, when the laser beam L is the blue light or the green light, and the wavelength λ of the laser beam L is between 440 nm and 540 nm, the energy gap width of the current confinement layer 14 should be greater than 2.3 eV.

In this way, a reduction of lighting efficiency of the surface emitting laser apparatus Z1 due to absorption of the laser beam L by the current confinement layer 14 can be avoided. In one embodiment, the energy gap width of the semiconductor material of the current confinement layer 14 is greater than an energy gap width of a semiconductor material of the trap layer.

Further, in the present embodiment, a lattice constant of the material of the current confinement layer 14 can match with a lattice constant of the material of the active light-emitting layer 12, so as to reduce interface defects. In one exemplary embodiment, a lattice mismatch between the material of the current confinement layer 14 and the material of the active light-emitting layer 12 is less than or equal to 0.1%. In addition, since the current confinement layer 14 of the present embodiment is disposed in the second reflector layer 13, a lattice mismatch between the material of the current confinement layer 14 and the material of the second reflector layer 13 is less than or equal to 0.1%.

That is, during selection of the material of the current confinement layer 14, the energy gap width and the lattice constant are taken into consideration. Accordingly, the energy gap width Eg of the current confinement layer 14 is greater than the energy gap width of the active light-emitting layer 12.

In one embodiment, the material of the current confinement layer 14 is the III-V group semiconductor that includes at least one of aluminum atoms, indium atoms, and gallium atoms, and can be expressed as AlₓIn_{y}Ga_{z}N, AlₓIn_{y}Ga_{z}P, or AlₓIn_{y}Ga_{z}As (in which 0≤x≤1, 0≤y≤1, 0≤z≤1, and x+y+z=1). For example, the material of the current confinement layer 14 can be aluminum gallium nitride (AlGaN), indium gallium nitride (InGaN), gallium nitride (GaN), aluminum nitride (AlN), indium aluminum phosphide (AlInP), indium gallium phosphide (InGaP), aluminum gallium phosphide (AlGaP), aluminum gallium arsenide (AlGaAs), aluminum arsenide (AlAs), or aluminum indium gallium arsenide (AlInGaAs).

It should be noted that an aluminum composition (x), an indium composition (y), and a gallium composition (z) can affect the energy gap width of the current confinement layer 14. The greater the aluminum composition (x) or the gallium composition (z) is, the larger the energy gap width of the current confinement layer 14 becomes. The greater the indium composition (y) is, the smaller the energy gap width of the current confinement layer 14 becomes. Accordingly, by controlling the aluminum composition (x), the indium composition (y), and the gallium composition (z), the energy gap width of the current confinement layer 14 can be adjusted to meet practical requirements.

For example, when the semiconductor material of the trap layer is InGaN, the material of the current confinement layer 14 can be AlGaN, InGaN, or GaN. When the semiconductor material of the trap layer is GaAs or InGaAs, the material of the current confinement layer 14 can be AlₓGa_{z}As, AlAs, or InGaP. Specifically, when the material of the current confinement layer 14 is AlₓGa_{z}As, by controlling the aluminum composition (x), the energy gap width of the current confinement layer 14 can be adjusted to meet the above requirements, and the lattice constant of the current confinement layer 14 can match with the lattice constants of the active light-emitting layer 12 and the second reflector layer 13.

Compared with a conventional oxide layer, the lattice mismatches between the current confinement layer 14 of the present embodiment and each of the active light-emitting layer 12 and the second reflector layer 13 are smaller. Accordingly, an internal stress of the surface emitting laser apparatus Z1 can be reduced, thereby improving reliability of the surface emitting laser apparatus Z1. In the present embodiment, a total thickness of the current confinement layer 14 is 10 nm to 1000 nm. Since the materials of the current confinement layer 14, the active light-emitting layer 12, and the second reflector layer 13 are all semiconductor materials, their difference of thermal coefficient of expansion can be relatively decreased. In this way, the surface emitting laser apparatus Z1 can be prevented from cracking (caused by the difference of thermal coefficient of expansion) after an annealing process, thereby improving a manufacturing yield.

It should be noted that, in the present embodiment, the current confinement layer 14 is disposed in the second reflector layer 13, and the second reflector layer 13 is a heavily doped semiconductor material. Accordingly, in one exemplary embodiment, the total thickness of the current confinement layer 14 is at least 30 nm, so as to prevent impurities in the second reflector layer 13 from diffusing to the current confinement layer 14 when a heat treatment is performed on the surface emitting laser apparatus Z1. The diffusion of the impurities can affect a polarity of the current confinement layer 14, such that the current can directly pass through and result in loss of a current confinement ability.

Referring to FIG. 1, the surface emitting laser apparatus Z1 of the embodiments of the present disclosure further includes a first electrode layer 15 and a second electrode layer 16. The first electrode layer 15 is electrically connected to the first reflector layer 11, and the second electrode layer 16 is electrically connected to the second reflector layer 13. In the embodiment shown in FIG. 1, the first electrode layer 15 and the second electrode layer 16 are disposed on different sides of the substrate 10, respectively. However, in another embodiment, the first electrode layer 15 and the second electrode layer 16 can both be disposed on the same side of the substrate 10.

Further, in the present embodiment, the first electrode layer 15 is disposed on the bottom surface 10b of the substrate 10. The second electrode layer 16 is disposed on the second reflector layer 13 and electrically connected to the second reflector layer 13. A current path through the active light-emitting layer 12 is defined between the first electrode layer 15 and the second electrode layer 16. Each of the first electrode layer 15 and the second electrode layer 16 can be a metal layer, an alloy layer, or a stacked layer made of different metal materials.

In the embodiment shown in FIG. 1, the second electrode layer 16 has an opening 16H for defining a light-emitting region A1, and the opening 16H corresponds to the confinement hole 14H of the current confinement layer 14, so as to allow the laser beam L produced by the active light-emitting layer 12 to emit from the opening 16H. In one embodiment, the second electrode layer 16 has a ring-shaped portion, but a top view pattern of the second electrode layer 16 is not limited in the present disclosure. A material of the second electrode layer 16 can be gold, tungsten, germanium, palladium, titanium, or any combination thereof.

In addition, the surface emitting laser apparatus Z1 further includes a current spreading layer 17 and a protection layer 18. The current spreading layer 17 is disposed on the second reflector layer 13 and electrically connected to the second electrode layer 16. In one embodiment, a material of the current spreading layer 17 is an electrically conductive material, so that the current injected into the active light-emitting layer 12 from the second reflector layer 13 is evenly distributed. In addition, the material of the current spreading layer 17 is a material that the laser beam L can pass through, so that the lighting efficiency of the surface emitting laser apparatus Z1 will not be overly sacrificed. For example, when the laser beam L has a wavelength of from 950 nm to 1,550 nm, the material of the current spreading layer 17 can be the doped semiconductor material, such as heavily-doped indium phosphide, but the present disclosure is not limited thereto.

The protection layer 18 covers the current spreading layer 17 and the light-emitting region A1, so as to prevent moisture from entering the surface emitting laser apparatus Z1 (which may affect lighting characteristics or the lifespan of the surface emitting laser apparatus Z1). In one embodiment, a material of the protection layer 18 can be a moisture-resistant material, such as silicon nitride, aluminum oxide, and a combination thereof, but the present disclosure is not limited thereto. In the present embodiment, the second electrode layer 16 is disposed on the protection layer 18, and passes through the protection layer 18 and the current spreading layer 17 to be connected to the second reflector layer 13, but the present disclosure is not limited thereto. In another embodiment, the current spreading layer 17 may also be omitted.

It is worth mentioning that at least a part of the current confinement layer 14 is arranged on the current path defined by the first electrode layer 15 and the second electrode layer 16. Accordingly, when a bias voltage is applied to the surface emitting laser apparatus Z1 through the first electrode layer 15 and the second electrode layer 16, the high resistance of the current confinement layer 14 drives the current to bypass the current confinement layer 14 and pass only through the confinement hole 14H, thereby increasing a current density of the current injected into the active light-emitting layer 12. Therefore, the lighting efficiency of the surface emitting laser apparatus Z1 can be improved.

### Second Embodiment

Referring to FIG. 2, FIG. 2 is a schematic cross-sectional view of a surface emitting laser apparatus according to a second embodiment of the present disclosure. Components of a surface emitting laser apparatus Z2 of the present embodiment that are the same as those of the surface emitting laser apparatus Z1 of the first embodiment are labeled by the same reference numerals, and the same components will not be reiterated herein. In the surface emitting laser apparatus Z2 of the present embodiment, the current confinement layer 14 is disposed in the second reflector layer 13, but is not connected to the active light-emitting layer 12. It should be noted that, in the present embodiment, the position of the current confinement layer 14 is adjacent to the active light-emitting layer 12 and away from the second electrode layer 16. In this way, the current injected into the active light-emitting layer 12 through the confinement hole 14H can be more concentrated, so that the surface emitting laser apparatus Z2 can have an improved lighting efficiency.

When the bias voltage is applied to the surface emitting laser apparatus Z2, the current is allowed to only pass through the confinement hole 14H of the current confinement layer 14. Accordingly, as long as the current confinement layer 14 can confine the current, the energy gap width of the intrinsic semiconductor of the current confinement layer 14 can meet the above requirements, and the lattice constant of the current confinement layer 14 can match with those of the active light-emitting layer 12 and the second reflector layer 13, the position of the current confinement layer 14 in the second reflector layer 13 is not limited in the present disclosure.

It is worth mentioning that, in the present embodiment, the current confinement layer 14 can be an intrinsic semiconductor layer or a doped semiconductor layer. When the current confinement layer 14 is the doped semiconductor layer, the current confinement layer 14 and the second reflector layer 13 have different conductivity types. For example, when the conductivity type of the second reflector layer 13 is a P-type, the conductivity type of the current confinement layer 14 can be an N-type. When the conductivity type of the second reflector layer 13 is the N-type, the conductivity type of the current confinement layer 14 is the P-type.

The second reflector layer 13 can be divided into an upper portion and a lower portion by the current confinement layer 14. The lower portion is arranged between the active light-emitting layer 12 and the current confinement layer 14, and the upper portion is arranged between the current confinement layer 14 and the second electrode layer 16. One P-N junction is formed between the current confinement layer 14 and the lower portion of the second reflector layer 13, and another P-N junction is formed between the current confinement layer 14 and the upper portion of the second reflector layer 13.

Under this circumstance, a Zener diode can be jointly formed by the current confinement layer 14 and the lower portion of the second reflector layer 13. Not only can the region through which the current flows be defined, but electrostatic protection can also be provided for the surface emitting laser apparatus Z2. Specifically, when the bias voltage is applied to the surface emitting laser apparatus Z2 through the first electrode layer 15 and the second electrode layer 16, the Zener diode is also applied with a reverse bias voltage, but is not broken down. Since the Zener diode is in a non-conductive state, the current is driven to bypass the current confinement layer 14 and only pass through the confinement hole 14H, thereby increasing the current density of the current injected into the active light-emitting layer 12.

However, when an electrostatic discharge is produced, the Zener diode is conductive regardless of whether an electrostatic current is a positive current or a negative current. Since a resistance of the Zener diode that is conductive is much lower than a resistance of the second reflector layer 13 arranged in the confinement hole 14H, most of the electrostatic current passes through the current confinement layer 14 instead of the confinement hole 14H. It should be noted that a top view area of the current confinement layer 14 is greater than a top view area of the confinement hole 14H. When the Zener diode is conductive, the electrostatic current flowing through the active light-emitting layer 12 can be dispersed to reduce the current density, so that damage to the active light-emitting layer 12 can be avoided. Accordingly, when the material of the current confinement layer 14 is the doped semiconductor, and the Zener diode is jointly formed by the current confinement layer 14 and the second reflector layer 13, the current pathway can be defined, and the current confinement layer 14 can also provide electrostatic discharge protection for the surface emitting laser apparatus Z2, thereby improving the reliability of the surface emitting laser apparatus Z2.

In another embodiment, the current confinement layer 14 can include the intrinsic semiconductor layer or the doped semiconductor layer, and the intrinsic semiconductor layer is arranged between the doped semiconductor layer and the lower portion of the second reflector layer 13, so as to achieve the above-mentioned effect.

### Third Embodiment

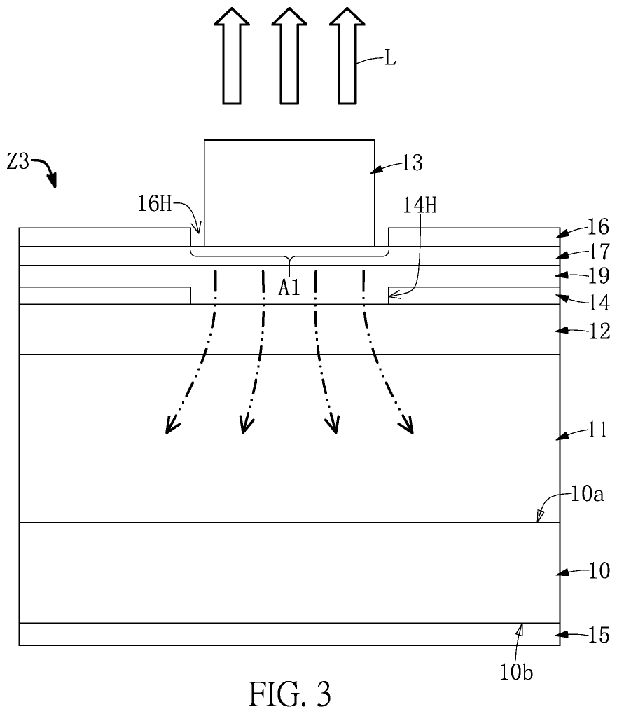

Referring to FIG. 3, FIG. 3 is a schematic cross-sectional view of a surface emitting laser apparatus according to a third embodiment of the present disclosure. Components of a surface emitting laser apparatus Z3 of the present embodiment that are the same as those of the surface emitting laser apparatus Z1 of the first embodiment are labeled by the same reference numerals, and the same components will not be reiterated herein.

In the surface emitting laser apparatus Z3 of the present embodiment, the current confinement layer 14 is arranged between the active light-emitting layer 12 and the second reflector layer 13, but the current confinement layer 14 is not disposed in the second reflector layer 13. Specifically, the surface emitting laser apparatus Z3 of the present embodiment further includes a current injection layer 19, and the current injection layer 19 is arranged between the current confinement layer 14 and the second electrode layer 16. In the present embodiment, a part of the current injection layer 19 is filled into the confinement hole 14H of the current confinement layer 14.

Further, in the present embodiment, a material of the current injection layer 19 is a doped semiconductor material, and the current injection layer 19 and the first reflector layer 11 have different conductivity types. In one embodiment, the semiconductor material of the current injection layer 19 can be the same as the semiconductor material of the current confinement layer 14, but the present disclosure is not limited thereto. The current confinement layer 14 can be the intrinsic semiconductor layer or the doped semiconductor layer. When the current confinement layer 14 is the doped semiconductor layer, the current confinement layer 14 and the current injection 19 layer have different conductivity types.

In another embodiment, the current confinement layer 14 can be not connected to the active light-emitting layer 12, but is embedded in the current injection layer 19. When the current confinement layer 14 includes the doped semiconductor layer, the current confinement layer 14 and the current injection layer 19 have different conductivity types. Accordingly, the Zener diode can be jointly formed by the current confinement layer 14 and the current injection layer 19, so as to provide the electrostatic protection for the surface emitting laser apparatus Z3.

The second electrode layer 16 can be electrically connected to the current injection layer 19 through the current spreading layer 17. When the bias voltage is applied to the surface emitting laser apparatus Z3, the current sequentially flows through the current injection layer 19 and the confinement hole 14H of the current confinement layer 14 before entering the active light-emitting layer 12.

Further, in the present embodiment, the second reflector layer 13 and the second electrode layer 16 are jointly disposed on the current spreading layer 17. Specifically, the second reflector layer 13 is arranged in the opening 16H defined by the second electrode layer 16. In other words, the second electrode layer 16 of the present embodiment surrounds the second reflector layer 13. It is worth mentioning that, in the present embodiment, the material of the second reflector layer 13 can include the semiconductor material, an insulation material, or a combination thereof. The semiconductor material can be an intrinsic semiconductor material or the doped semiconductor material, but the present disclosure is not limited thereto. For example, the semiconductor material can be silicon, indium gallium aluminum arsenide (InGaAlAs), indium gallium arsenide phosphide (InGaAsP), indium phosphide (InP), indium aluminum arsenide (InAlAs), aluminum gallium arsenide (AlGaAs), or aluminum gallium nitride (AlGaN), and is selected according to the wavelength of the laser beam L. The insulation material can be oxides or nitrides (such as silicon oxide, titanium oxide, and aluminum oxide), but the present disclosure is not limited thereto. For example, the second reflector layer 13 can include multiple pairs of film layers. Each pair of the film layers can be a titanium oxide layer and a silicon oxide layer, a silicon layer and an aluminum oxide layer, or the titanium oxide layer and the aluminum oxide layer, and can be determined according to the wavelength of the laser beam L to be produced. However, the present disclosure is not limited thereto.

### Fourth Embodiment

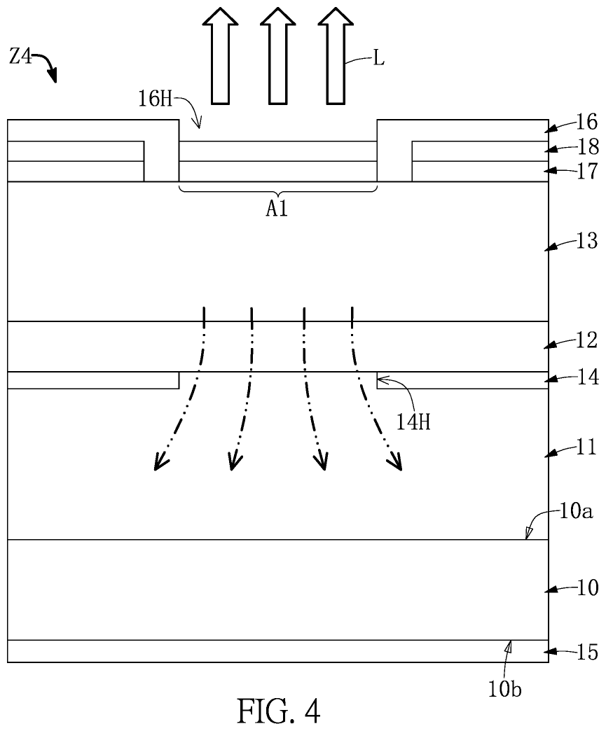

Referring to FIG. 4, FIG. 4 is a schematic cross-sectional view of a surface emitting laser apparatus according to a fourth embodiment of the present disclosure. Components of a surface emitting laser apparatus Z4 of the present embodiment that are the same as those of the surface emitting laser apparatus Z1 of the first embodiment are labeled by the same reference numerals, and the same components will not be reiterated herein. The current confinement layer 14 is arranged between the active light-emitting layer 12 and the first reflector layer 11. Specifically, in the present embodiment, the current confinement layer 14 can be embedded in the first reflector layer 11 and connected to the active light-emitting layer 12. In addition, the current confinement layer 14 can be the intrinsic semiconductor layer, and the energy gap width thereof is greater than 0.8 eV and less than 1.4 eV, or is greater than 2.3 eV.

### Fifth Embodiment

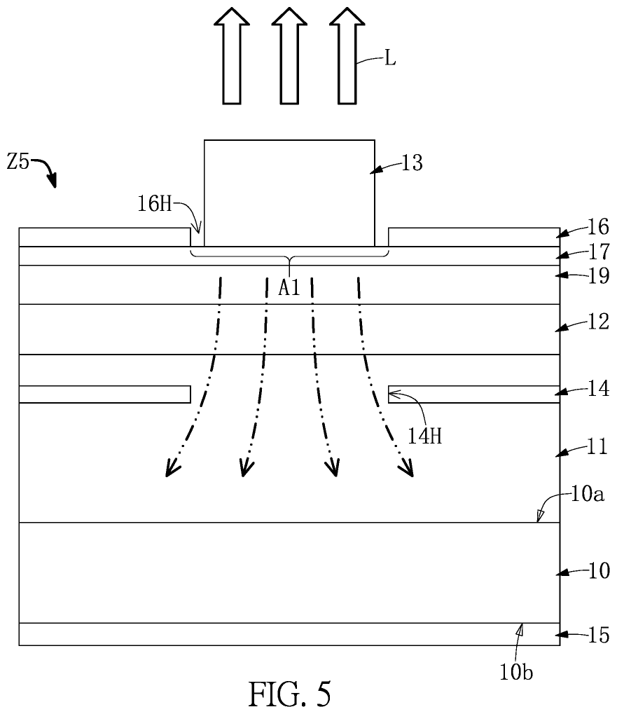

Referring to FIG. 5, FIG. 5 is a schematic cross-sectional view of a surface emitting laser apparatus according to a fifth embodiment of the present disclosure. Components of a surface emitting laser apparatus Z5 of the present embodiment that are the same as those of the surface emitting laser apparatus Z3 of the third embodiment are labeled by the same reference numerals, and the same components will not be reiterated herein. In the present embodiment, the current confinement layer 14 is embedded in the first reflector layer 11 but not connected to the active light-emitting layer 12. In one exemplary embodiment, the position of the current confinement layer 14 is adjacent to the active light-emitting layer 12 and away from the substrate 10.

It is worth mentioning that, the current confinement layer 14 of the present embodiment can include the intrinsic semiconductor layer, the doped semiconductor layer, or a combination thereof. When the current confinement layer 14 is the doped semiconductor layer, the current confinement layer 14 and the first reflector layer 11 have different conductivity types. For example, when the conductivity type of the first reflector layer 11 is the N-type, the conductivity type of the current confinement layer 14 can be the P-type. When the conductivity type of the first reflector layer 11 is the P-type, the conductivity type of the current confinement layer 14 is the N-type.

The first reflector layer 11 can be divided into an upper portion and a lower portion by the current confinement layer 14. The upper portion is arranged between the current confinement layer 14 and the active light-emitting layer 12, and the lower portion is arranged between the substrate 10 and the current confinement layer 14. Accordingly, two P-N junctions are formed between the current confinement layer 14 and the first reflector layer 11. Further, the Zener diode can be jointly formed by the current confinement layer 14 and the upper portion of the first reflector layer 11. Not only can the region through which the current flows be defined, but the electrostatic protection can also be provided for the surface emitting laser apparatus Z5.

When the bias voltage is applied to the surface emitting laser apparatus Z5 through the first electrode layer 15 and the second electrode layer 16, the Zener diode is applied with the reverse bias voltage, but is not broken down. Since the Zener diode is in the non-conductive state, the current is driven to bypass the current confinement layer 14 and only pass through the confinement hole 14H, thereby increasing the current density of the current injected into the active light-emitting layer 12.

However, when the electrostatic discharge is produced, the Zener diode is conductive regardless of whether the electrostatic current is the positive current or the negative current, and most of the electrostatic current passes through the current confinement layer 14 instead of the confinement hole 14H. According to the above, the top view area of the current confinement layer 14 is greater than the top view area of the confinement hole 14H. When the Zener diode is conductive, the electrostatic current flowing through the active light-emitting layer 12 can be dispersed to reduce the current density, so that damage to the active light-emitting layer 12 can be avoided. Accordingly, when the material of the current confinement layer 14 is the doped semiconductor, and the Zener diode is jointly formed by the current confinement layer 14 and the first reflector layer 11, the current pathway can be defined, and the current confinement layer 14 can also provide the electrostatic discharge protection for the surface emitting laser apparatus Z5, thereby improving the reliability of the surface emitting laser apparatus Z5.

In another embodiment, the current confinement layer 14 can include the intrinsic semiconductor layer or the doped semiconductor layer, and the intrinsic semiconductor layer is arranged between the doped semiconductor layer and the upper portion of the first reflector layer 11, so as to achieve the above-mentioned effect.

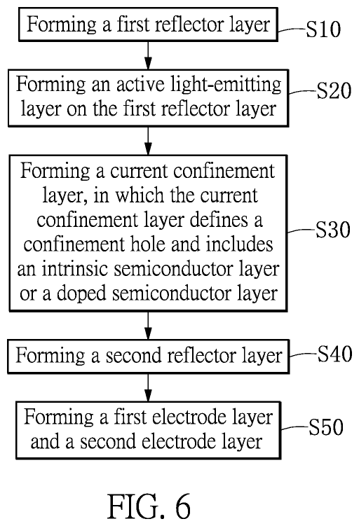

Referring to FIG. 6, FIG. 6 is a flowchart of a method for manufacturing a surface emitting laser apparatus according to one embodiment of the present disclosure. In step S10, a first reflector layer is formed. In step S20, an active light-emitting layer is formed on the first reflector layer. In step S30, a current confinement layer is formed on the active light-emitting layer. The current confinement layer defines a confinement hole and includes an intrinsic semiconductor layer or a doped semiconductor layer. In step S40, a second reflector layer is formed. In step S50, a first electrode layer and a second electrode layer are formed.

It is worth mentioning that the method provided in the embodiments of the present disclosure can be used to manufacture the surface emitting laser apparatus Z1 to Z5. Referring to FIG. 5 to FIG. 10, manufacturing of the surface emitting laser apparatus Z1 is taken as an example for illustrative purposes.

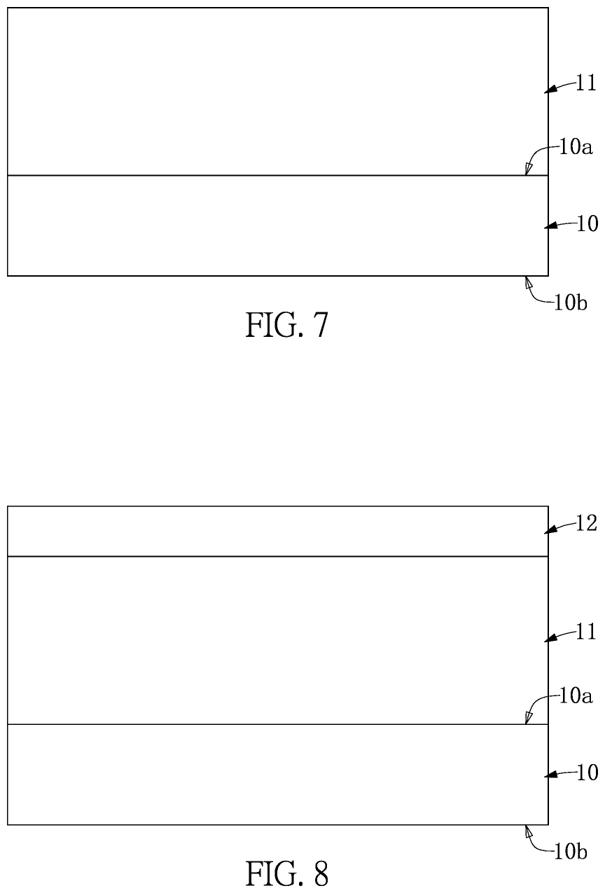

As shown in FIG. 7, the first reflector layer 11 is formed on the substrate 10. Specifically, the first reflector layer 11 is formed on the epitaxial surface 10a of the substrate 10. The material of the substrate 10 has been described above, and will not be reiterated herein. The substrate 10 and the first reflector layer 11 can have the same conductivity type.

As shown in FIG. 8, the active light-emitting layer 12 is formed on the first reflector layer 11. The active light-emitting layer 12 can be formed by alternately forming the plurality of trap layers and the plurality of barrier layers on the first reflector layer 11. In one embodiment, the first reflector layer 11 and the active light-emitting layer 12 can be formed on the epitaxial surface 10a of the substrate 10 by a chemical vapor deposition process.

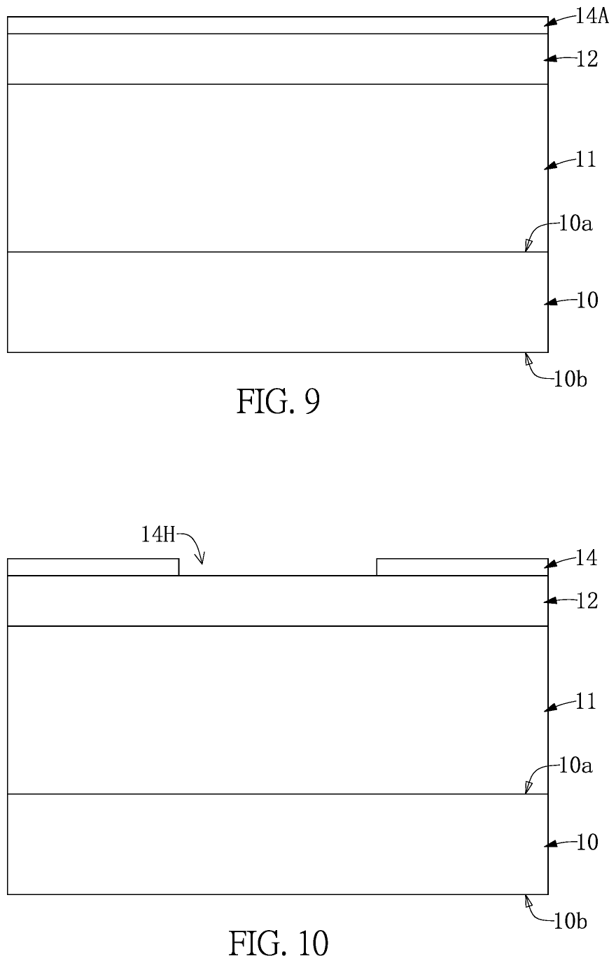

Referring to FIG. 9 and FIG. 10, a detailed process of forming the current confinement layer 14 on the active light-emitting layer 12 is shown. Specifically, an initial semiconductor layer 14A is first formed on the active light-emitting layer 12, and the initial semiconductor layer 14A can include the intrinsic semiconductor layer, the doped semiconductor layer, or the combination thereof. Referring to FIG. 10, in the present embodiment, the confinement hole 14H is then formed in the initial semiconductor layer 14A to expose a part of the active light-emitting layer 12. Further, the confinement hole 14H can be formed in the initial semiconductor layer 14A by an etching process.

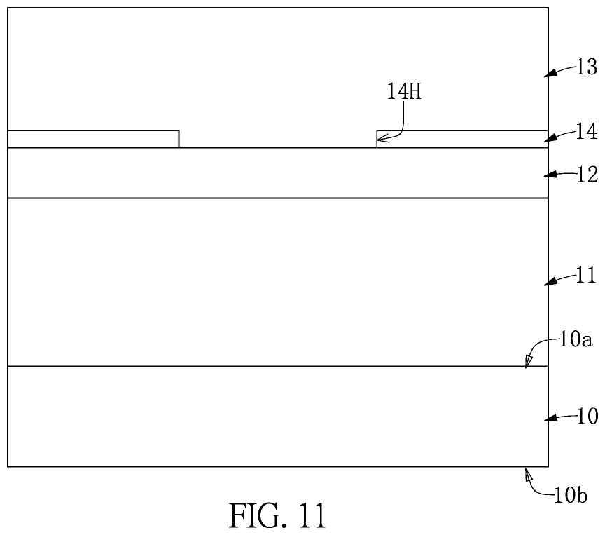

Referring to FIG. 11, the second reflector layer 13 is formed on the current confinement layer 14 and the active light-emitting layer 12. Specifically, during formation of the second reflector layer 13, one part of the second reflector layer 13 is filled into the confinement hole 14H and connected to the active light-emitting layer 12.

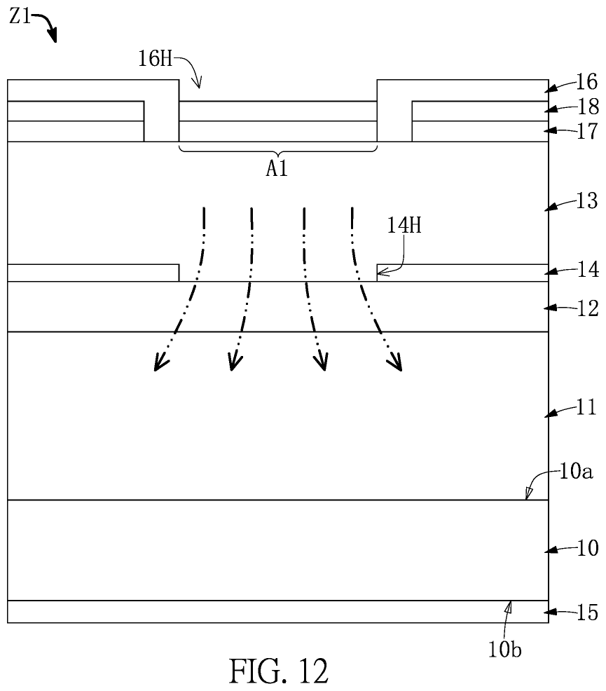

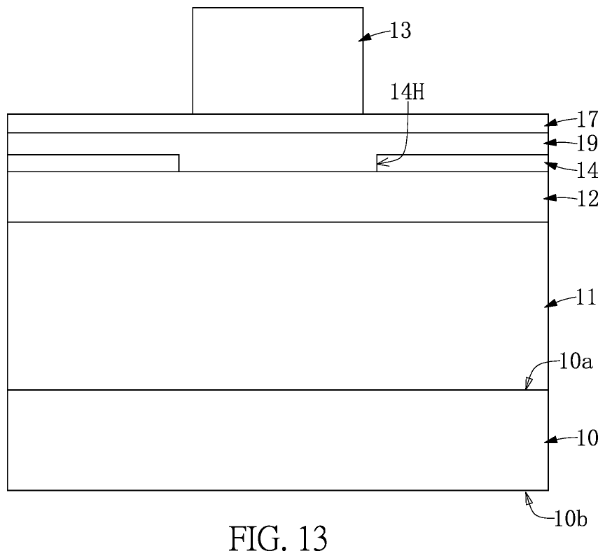

Referring to FIG. 12, the first electrode layer 15 is formed on the bottom surface 10b of the substrate 10, and the second electrode layer 16 is formed on the second reflector layer 13, so as to manufacture the surface emitting laser apparatus Z1 of the first embodiment of the present disclosure. In the present embodiment, the current spreading layer 17 and the protection layer 18 can be formed before formation of the second electrode layer 16.

It should be noted that, when the surface emitting laser apparatus Z2 of the second embodiment is being manufactured, the one part of the second reflector layer 13 can be formed on the active light-emitting layer 12, and then the current confinement layer 14 with the confinement hole 14H is formed. Afterwards, another part of the second reflector layer 13 is regrown on the current confinement layer 14.

Reference is made to FIG. 13, which shows the step following the step of FIG. 10. The method of the embodiments of the present disclosure further includes: forming the current injection layer 19 on the current confinement layer 14. In the present embodiment, the step of forming the current injection layer 19 is performed before the step of forming the second reflector layer 13. As shown in FIG. 13, the current injection layer 19 is formed in the confinement hole 14H of the current confinement layer 14 and connected to the active light-emitting layer 12. Afterwards, the current spreading layer 17 and the second reflector layer 13 are formed on the current injection layer 19.

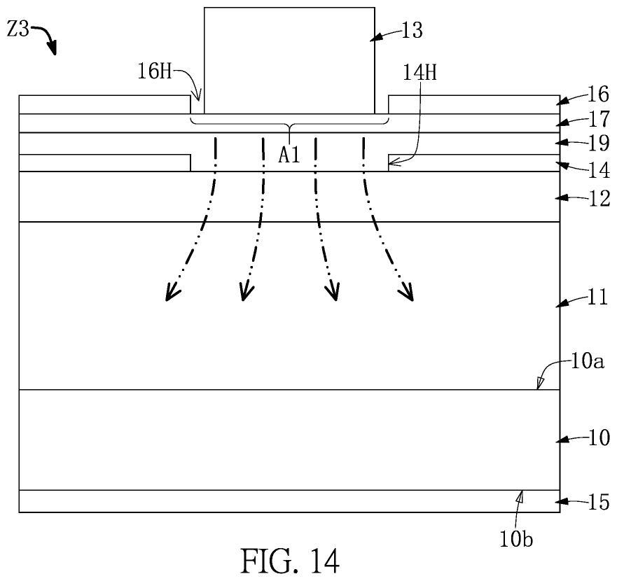

Referring to FIG. 14, the first electrode layer 15 is formed on the bottom surface 10b of the substrate 10, and the second electrode layer 16 is formed on the current spreading layer 17, so that the second electrode layer 16 is electrically connected to the current injection layer 19. In addition, the second electrode layer 16 has the opening 16H that corresponds to the confinement hole 14H, and the second electrode layer 16 surrounds the second reflector layer 13. In other words, the second reflector layer 13 is arranged in the opening 16H defined by the second electrode layer 16. In one embodiment, after the current spreading layer 17 is formed, the second reflector layer 13 is formed before the second electrode layer 16. In another embodiment, the step of forming the second reflector layer 13 and the step of forming the second electrode layer 16 can be switched. By performing the above steps, the surface emitting laser apparatus Z3 of the third embodiment can be manufactured.

It should be noted that, when the surface emitting laser apparatus Z4 of the fourth embodiment is being manufactured, the step S30 of forming the current confinement layer 14 can be performed before the step S20 of forming the active light-emitting layer 12. When the surface emitting laser apparatus Z5 of the fifth embodiment is being manufactured, the lower portion of the first reflector layer 11 can be formed before the current confinement layer 14 with the confinement hole 14. Afterwards, the upper portion of the first reflector layer 11 is regrown on the current confinement layer 14.

### Beneficial Effects of the Embodiments

In conclusion, one of the beneficial effects of the present disclosure is that, in the surface emitting laser apparatus and the method for manufacturing the same provided by the present disclosure, by virtue of “the current confinement layer 14 being the semiconductor layer” and “the energy gap width of the current confinement layer 14 being greater than 0.8 eV and less than 1.4 eV, or being greater than 2.3 eV,” the internal stress of the surface emitting laser apparatus Z1 to Z5 can be reduced, thereby allowing the surface emitting laser apparatus Z1 to Z5 to have an improved lighting efficiency and improved reliability.

In addition, since each of the first reflector layer 11, the current confinement layer 14, the active light-emitting layer 12, and the second reflector layer 13 is made of the semiconductor material, their difference of thermal coefficient of expansion is small. In this way, the surface emitting laser apparatus Z1 to Z5 can be prevented from breaking (caused by the difference of thermal coefficient of expansion) after the annealing process, thereby improving the manufacturing yield. Furthermore, through an appropriate selection of the semiconductor material of the current confinement layer 14, the lattice mismatch between the current confinement layer 14 and the active light-emitting layer 12, between the current confinement layer 14 and the second reflector layer 13, or between the current confinement layer 14 and the current injection layer 19 can be decreased, so that the internal stress of the surface emitting laser apparatus Z1 to Z5 can be reduced. Therefore, the reliability of the surface emitting laser apparatus Z1 to Z5 can be further improved.

Since an oxide layer can be absent from the surface emitting laser apparatus Z1 to Z5 of the embodiments of the present disclosure, a step of performing a lateral oxidation process can be omitted during manufacturing of the surface emitting laser apparatus Z1 to Z5 of the embodiments of the present disclosure. In addition, it is not necessary to form a lateral groove in the surface emitting laser apparatus Z1 to Z5 of the embodiments of the present disclosure. Accordingly, the process of manufacturing the surface emitting laser apparatus Z1 to Z5 can be simplified, and manufacturing costs can be reduced. Moreover, entry of moisture into an interior of the surface emitting laser apparatus Z1 to Z5 during the lateral oxidation process (which may affect the light-emitting characteristics of the surface emitting laser apparatus Z1 to Z5) can be avoided. Therefore, the surface emitting laser apparatus Z1 to Z5 of the embodiments of the present disclosure can have a high reliability.

Further, when the Zener diode is jointly formed by the current confinement layer 14 and the first reflector layer 11 or by the current confinement layer 14 and the second reflector layer 13, the current pathway can be defined, and the current confinement layer 14 can also provide the electrostatic discharge protection for the surface emitting laser apparatus Z1 to Z5.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A surface emitting laser apparatus, comprising:
a first reflector layer;
an active light-emitting layer;
a second reflector layer, wherein the active light-emitting layer is disposed between the first reflector layer and the second reflector layer, so as to produce a laser beam; and
a current confinement layer disposed above or below the active light-emitting layer, wherein the current confinement layer is a semiconductor layer, and an energy gap width of the current confinement layer is greater than 0.8 eV and less than 1.4 eV, or is greater than 2.3 eV.

2. The surface emitting laser apparatus according to claim 1, wherein the current confinement layer is disposed in the second reflector layer, and a lattice mismatch between a material of the second reflector layer and an intrinsic semiconductor is less than 0.1%.

3. The surface emitting laser apparatus according to claim 1, wherein a thickness of the current confinement layer is at least 30 nm.

4. The surface emitting laser apparatus according to claim 1, wherein a material of the current confinement layer is aluminum gallium nitride (AlGaN), indium gallium nitride (InGaN), gallium nitride (GaN), aluminum nitride (AlN), indium aluminum phosphide (AlInP), indium gallium phosphide (InGaP), aluminum gallium phosphide (AlGaP), aluminum gallium arsenide (AlGaAs), or aluminum arsenide (AlAs).

5. The surface emitting laser apparatus according to claim 1, wherein the active light-emitting layer includes a plurality of trap layers and a plurality of barrier layers that are alternately stacked on each other, and an energy gap width of the trap layer is less than the energy gap width of the current confinement layer.

6. The surface emitting laser apparatus according to claim 1, further comprising:
a current injection layer;
wherein a part of the current injection layer is filled into a confinement hole of the current confinement layer, and the second reflector layer is disposed above the current injection layer.

7. The surface emitting laser apparatus according to claim 6, wherein the current confinement layer is disposed in the current injection layer, and the current confinement layer is an intrinsic semiconductor layer or has a conductivity type that is different from a conductivity type of the current injection layer.

8. The surface emitting laser apparatus according to claim 1, wherein the current confinement layer is disposed in the second reflector layer and not connected to the active light-emitting layer; wherein the current confinement layer is an intrinsic semiconductor layer or has a conductivity type that is different from a conductivity type of the second reflector layer.

9. The surface emitting laser apparatus according to claim 1, wherein the current confinement layer is disposed in the first reflector layer and not connected to the active light-emitting layer; wherein the current confinement layer is an intrinsic semiconductor layer or has a conductivity type that is different from a conductivity type of the first reflector layer.

10. A surface emitting laser apparatus, comprising:
a first reflector layer;
an active light-emitting layer;
a second reflector layer, wherein the active light-emitting layer is disposed between the first reflector layer and the second reflector layer, so as to produce a laser beam; and
a current confinement layer disposed in the first reflector layer or the second reflector layer and including at least one doped semiconductor layer;
wherein, when the current confinement layer is disposed in the first reflector layer, the at least one doped semiconductor layer and the first reflector layer have different conductivity types;
wherein, when the current confinement layer is disposed in the second reflector layer, the at least one doped semiconductor layer and the second reflector layer have different conductivity types.

11. A method for manufacturing a surface emitting laser apparatus, comprising:
forming a first reflector layer;
forming an active light-emitting layer on the first reflector layer;
forming a current confinement layer, wherein the current confinement layer defines a confinement hole and includes an intrinsic semiconductor layer or a doping semiconductor layer; and
forming a second reflector layer.

12. The method according to claim 11, wherein the step of forming the current confinement layer includes:
forming an initial semiconductor layer on the active light-emitting layer; and
forming the confinement hole in the initial semiconductor layer, so as to expose a part of the active light-emitting layer;
wherein, after the step of forming the second reflector layer, a part of the second reflector layer is filled into the confinement hole.

13. The method according to claim 11, further comprising:
forming, before the step of forming the second reflector layer, a current injection layer on the current confinement layer, wherein a part of the current injection layer is filled into the confinement hole; and
forming a first electrode layer and a second electrode layer, wherein the first electrode layer is electrically connected to the first reflector layer, and the second electrode layer is electrically connected to the injection layer and surrounds the second reflector layer;
wherein the second electrode layer has an opening for defining a light-emitting region, and the opening corresponds to the confinement hole.
